(19) United States
(12) Patent Application Publication
(10) Pub. No.: US 2014/0297072 A1
(43) Pub. Date: Oct. 2, 2014

(54) GROUP OF SYSTEMS FOR MAKING A SOLAR ELECTRIC VEHICLE MORE PRACTICAL

(71) Applicant: Benjamin David Freeman, Newtown Sq., PA (US)

(72) Inventor: Benjamin David Freeman, Newtown Sq., PA (US)

(21) Appl. No.: 13/971,997

(22) Filed: Aug. 21, 2013

Related U.S. Application Data
(60) Provisional application No. 61/805,971, filed on Mar. 28, 2013.

(51) Int. Cl. H01L 31/042; B60L 8/00

(52) U.S. Cl. CPC H01L 31/0422; B60L 8/003
USPC 701/22; 136/246

(57) ABSTRACT

The device is a group of mechanisms and three types of related computer functions that work together and with the driver to optimize the operation of an electric vehicle with a deployable solar array. The purposes of doing so are to keep the vehicle and its constituent parts undamaged and safe, to orient the solar array towards the sun for maximal electricity generation and to make sure that the vehicle's battery array maintains a proper and appropriate charge.

### BACKGROUND OF THE INVENTION

Five years ago, no company that also sold significant numbers of gas driven cars was selling electric vehicles commercially. Five years from now, the majority of major car companies will probably be selling some form of electric vehicles. And yet there are serious problems. The range limitations of electric cars are exacerbated by the fact that people have difficulty recharging their vehicles. Just as the difficulty of finding recharging stations makes people shy away from buying and using electric cars, the lack of customers and the difficulties potential customers have in finding electric recharging stations discourages people from opening electric recharging stations.

In addition to electric recharging stations there is one other way to recharge the batteries of an electric vehicle. Many individuals and companies have mounted solar panels on an electric vehicle to extend its range. But mounting solar panels on the available space on the roof, hood and cargo area does not significantly increase a vehicle's range. One can generate much more electricity if a solar array mounted on a vehicle extended far beyond the vehicle perimeter. However, driving and entering such a vehicle would create all sorts of problems.

The solution is to mount a solar array on a vehicle where solar panels do not extend far beyond the perimeter of the vehicle when it is being driven—but which then is deployed to new positions when the vehicle is parked. For instance, one could stack up four solar panels on a vehicle roof when it is being driven and then deploy these solar panels to positions where each panel occupies one quadrant of a much larger parking space sized rectangle when the vehicle is parked. In addition to the present inventor, a handful of others have developed this type of system.

Of course, deployable or expandable solar systems also have problems. They are vulnerable to strong winds and other types of extreme weather while they are being deployed. Even when an array can be deployed without danger, changes in weather conditions may make it necessary to retract the array to a safer undeployed position while it is parked. Trees, buildings and taller trucks which didn't shade the solar array when it was undeployed may shade it when it is deployed. While a vehicle is parked for hours, the movement of the sun changes whether a solar array is properly positioned for maximal solar energy generation. Hence, a way has to be found to change the position of the solar array to account for changes in shading patterns and changes in the position of the sun.

Proper positioning of a solar array which is close to horizontal at noon can make as much as a forty percent difference in electricity generation during the early morning and late afternoon hours. Many people have used formal two axis trackers or other complex systems to properly orient stationary solar arrays. But placing a two axis tracker or any of the other complex solar orientation devices used for stationary arrays on a moving vehicle is problematical. In fact, the complexities of integrating a formal two axis tracker system into a vehicle solar array is a major reason that a vehicle system with a two axis tracker required to orient the solar array to the sun fails to adequately solve the problem. As the present invention shows, there is no need to use such a complex system on a moving vehicle. Instead, we can use the ability of the driver to pre-position a moving vehicle in the best possible parking space and in the best possible direction when parking to simplify the system which one uses to orient the solar array of a moving vehicle. But even with the type of simplified orientation system which makes the most sense for a moving vehicle, it is a somewhat complex engineering and mathematical problem to calculate how to orient it perfectly and then to change its orientation as the sun moves through the sky.

Solving any of the problems mentioned in this section requires careful calculation. In fact, the level of calculation required to deal appropriately with these problems requires an onboard computer. And because both weather and the position of the sun changes, the onboard computer must be able to act and give advice to the driver in a way which changes over time

### BRIEF DESCRIPTION OF THE INVENTION

The present invention is basically a system for extending the range of a solar electric vehicle and protecting the vehicle and its parts from unnecessary damage. Like most systems, however, there are sub-systems which collectively make up the one larger system. Three of the five sub-systems in the present invention specifically involve an onboard computer and another one of these five sub-systems involves a group of mechanisms which collectively constitute an inexpensive and simple way to position and reposition a deployable solar array on a motorized vehicle to create an appropriate tilt of the solar array which is modified slightly as the sun moves across the sky. The fifth subsystem involves the driver choosing the parking space and parking direction which works best with the type of positioning made possible by the vehicle's mechanisms to maximize solar energy generation. To do this, however, the present invention contemplates that the onboard computer and other aids will give him some of the information required to know how to do this at the moment and in the place where he intends to park. Since “practice makes perfect,” using the same vehicle many times will make it much easier for the driver as he or she familiarizes themselves with what the mechanisms can do, the tilt possibilities available on the vehicle and the abilities of the onboard computer.

The first step in positioning the array is for the driver to choose the available parking space and parking direction which will make it possible for the array to be tilted and positioned in a way that will maximize solar electricity generation during the specific period of time when he or she plans to park. To aid the driver in this effort, an onboard computer will offer advice based on a projection of how the sun will move across the sky during the proposed parking period and how that will affect how nearby objects might shade parts of the deployed solar array during the proposed parking period. Precisely because sunlight reaches particular areas at different angles at different times of the year and the sun moves across the sky every day, no static list of which parking spaces are good or bad could be compiled. Instead, the computer and driver must be able to work together to consider how the most appropriate parking space and parking direction can change due to the way the position of the sun varies from one time to another one.

The non-computer based mechanical sub-system basically consists of mechanisms which have two different, yet related, functions. One set of mechanisms will move the solar panels from their undeployed position to a deployed position where the solar panels at one end (either the front or back) of the vehicle are higher than those at the other end and where those in the middle are at an intermediate height. While this first set of mechanisms will move the solar panels towards the same position virtually every time that the array is deployed, the second set of mechanisms will modify the tilt of the array over time to track the sun as it moves across the sky. This second set of mechanisms could involve repositioning the vehicle or it could be limited to only repositioning the solar array. While repositioning the solar array without repositioning the vehicle seems superficially to be less expensive, it depends on the exact deployment system chosen whether it is, in fact, less expensive to tilt the entire vehicle or to only tilt the entire array. And even if the cost factor is close, the type of internal jacks that would tilt the entire vehicle have the secondary advantage of making it easier to change tires or to do vehicle repairs. On the other hand, tilting the entire vehicle to track the sun could cause cargo left in a parked vehicle to slide. Because there are pros and cons about both possibilities, the present invention could be implemented using internal jacks that move the entire vehicle or using internal jacks that only move the solar panels and some related mechanisms and shelves. Especially considering that automotive technology will likely enter an era where fuel efficiency continues to grow in importance, two additional factors suggest the usefulness of the kind of jack arrangement disclosed in accordance with the present invention. For one thing, cars will be light and easy to lift. For another, the heavy, inefficient rotating mass associated with 4-wheel drive will have to be foregone in many cases in favor of simple reliance on a second, winter set of tires. Thus, private maintenance of tires is likely to become more commonplace.

One could theoretically reposition the solar array to track the sun without an onboard computer. In practice, however, this would be difficult for an engineer and virtually impossible for the average driver. And even if someone was able and willing to reposition the solar array and the internal jacks by pushing buttons and doing the required computations without a computer, there would still be the need to reposition the array as the sun moved during the few hours when a parked vehicle was left unattended.

Therefore, one of the computer-based sub-systems is specifically involved with controlling the mechanisms which reposition the solar panels and deploying the internal jacks to maximize solar energy output.

But opening and expanding an array to maximize the area exposed to the sun and tilting the array to track the sun will often put solar panels, mechanisms and the vehicle itself in a vulnerable position. The potential vulnerability will be increased if one is parked on a hill. Especially in extreme weather, it may be necessary to retract the array to the less vulnerable undeployed position it typically assumes when the vehicle is being driven

Hence, the vehicle needs a second computer-based subsystem for determining whether the danger of an array remaining in a more vulnerable position outweighs the value of the electricity being generated at any given time. If it makes sense to retract the array and any associated mechanisms, then the driver has to be alerted or this retraction has to be done automatically once the dangers outweigh the advantages. Quite obviously, the calculations required to do what needs to be done can only be accomplished by an onboard computer. And since a decision must often be made when the vehicle is parked and the driver is busy doing something in a building away from the vehicle, a computer type system will also be needed to decide whether to retract the array in many circumstances. Furthermore, there are intermediate states where the pros and cons of various alternatives have to be carefully weighed. In practice, it is impossible to determine whether the pros of changing the positioning outweigh the cons without looking at the situation from the perspective of computer function one and of computer function two simultaneously. Therefore, the two computer based systems actually work together. Because both of these computer based systems are involved with controlling the same solar panel repositioning mechanisms and the same systems for controlling the internal jacks, neither of these aforementioned computer based systems makes nearly as much sense on its own as it does when working in combination with the other one(s).

Even for a “plug in” electric vehicle without any solar support, one could have an onboard computer help one determine whether it makes sense to stop at a battery recharging station and to use a GPS system to find the appropriate station from a list which is preprogrammed into an onboard computer. But the addition of a solar charging component makes the calculations required to determine whether, where and when it makes sense to stop far more complicated. Because of this, the addition of a third computer function in this area is a necessary subsystem of the larger system and purpose of the present invention.

To help one visualize the variety of ways where the decision about whether, where and when to stop at an electric recharging station is a necessary function for an onboard computer on a vehicle with a deployable solar array, consider the following:

Since part of the advantage of having a solar array is to reduce the use of “plug in” electricity, careful calculation to minimize the times one stops to recharge the battery (or other energy storage) system is far more important for a solar electric vehicle than for one whose only form of recharging is “plug in” electricity.

Calculating whether a solar vehicle can get to a destination chosen by the driver without damaging the battery array and without running out of fuel on the way is inextricably interwoven with understanding how much electricity the solar array will generate while the vehicle is being driven to its destination.

Particularly when calculation reveals that the existing battery charge plus the projected solar generation during a drive will leave one with just enough of a charge to make the drive without causing long-term damage to the battery array, it becomes relevant to know how much further charging will occur before the vehicle is going to be driven the next time. Knowing how much further charging will occur often requires knowledge of how much daylight will be left when the vehicle is parked at its first destination. And if the vehicle will be parked overnight at its first destination, it is also necessary to know how much morning time the array can be charging before the vehicle will be driven the next day. Additionally, it is useful to know how far one is intending to drive the vehicle the next day and whether it is possible to use a “plug in” electric recharging capacity at ones overnight destination.

With all these points in mind (especially number three above), the weather forecast and the way that the sun is projected to move across the sky become very important points. If, for instance, most of the time between now and the next time that the driver intends to use the vehicle will primarily be during the night and the future twenty four hour forecast suggests that the remainder of this time will be overcast, the amount of projected electricity generated will be very low. On the other hand, if there will be twenty hours of very high intensity sunlight before the next time that the vehicle is being driven, then the amount of electricity generated will be much higher. Which of these last two scenarios is projected to occur will have a huge effect on determining whether it makes sense to recharge the vehicle at a “Plug in” electric recharging station on the way. Since the weather forecasting and projections of the sun's movement are integrally related to the computer function discussed just before this one, we see that the same weather forecasting and sun tracking systems will also be needed for determining when and whether to stop to recharge the batteries. Similarly, there are a variety of other ways where one function needed for one of the three computer based subsystems is also needed for another one.

Even besides the need to use these computer based systems to work together and with the driver to control the vehicle and its systems, there are a few specific ways that the onboard computer is needed to help the driver determine how to park or drive the vehicle. For instance, the decision about whether to use a solar electric vehicle for a longer trip can only be made by the driver if he or she is sure that it can be made without running out of battery charge or reducing the battery charge to an unsafe level. Especially if one lives in an area where there are only a very limited number of electric recharging stations available at any given time, all three of the aforementioned computer based systems would have to work together and use all their pre-programmed knowledge to be able to give the driver the information they need to determine whether it is advisable to use this vehicle to make a particular trip at a particular time. Similarly, the decision about which parking space to take and which direction to park the car cannot be made intelligently without reference to knowledge and computational abilities which the various computer based systems have. Hence, the three computer based functions and the mechanical and driver decision components discussed in the present invention are really sub-systems of one larger system for appropriately making and using an electric vehicle with a deployable solar array.

Before moving on to the drawings and their detailed description, a clear definition of what is meant by the term “internal jacks” Is given as follows. An internal jack is a mechanism or a group of mechanisms built into the vehicle which will either tilt the solar array without tilting the vehicle or which will tilt both the vehicle and the solar array together. Sometimes, in the context of moving the vehicle alone, these jacks are referred to in this document as vehicle-mounted.

The present document uses the word jack to help connect it to the of type hydraulic jack typically used to raise one corner of a vehicle when one changes a tire. One example of an internal jack would be similar hydraulic, pneumatic or electric jack which has the same function but where the part of the jack that projects outward comes downward from inside the vehicle to touch the ground rather than coming upwards from a ground based jack to touch the vehicle. Although the word jack and the type of jack portrayed in some of the drawings fits this last description, the type of totally different form of internal jack which moves the solar array without moving the vehicle would tend to look more like a vertical actuator raising a shelf, platform or solar panel. Another alternative method for moving the vehicle might involve raising the body just above one or two wheels at a time in the way that some vehicles do in rough terrain and or for other purposes. But whether one uses any of these types of mechanisms or something else entirely, the bottom line is that any mechanism whose use can create the effect of quickly changing the tilt of solar panels on a vehicle from one minute to the next is labeled an “internal jack” for purposes of the present invention.

### BRIEF DESCRIPTION OF THE SEVERAL VIEWS OF THE DRAWINGS

FIG. 1 Is a depiction of the procedure which will be used to properly orient the solar panels towards the sun.

FIG. 2: Is a depiction of the procedure which the onboard computer will use to protect the solar array from extreme weather

FIG. 3: Is a depiction of the procedure which the onboard computer will use to give the driver the information they need to know when and where to recharge the batteries.

FIG. 4: Is a depiction of one way that a deployed solar array would look in the present invention

FIG. 5: Is a depiction of another way that a deployed solar array would look in the present invention

FIG. 6: Is a depiction of one side of a vehicle where one internal jack is not deployed and another one is deployed

FIG. 7: Is a depiction a vehicle-mounted or internal jack for use in carrying out the methods of the present invention.

FIG. 8: Is a flowchart showing particular steps to be carried out in certain embodiments of the present invention.

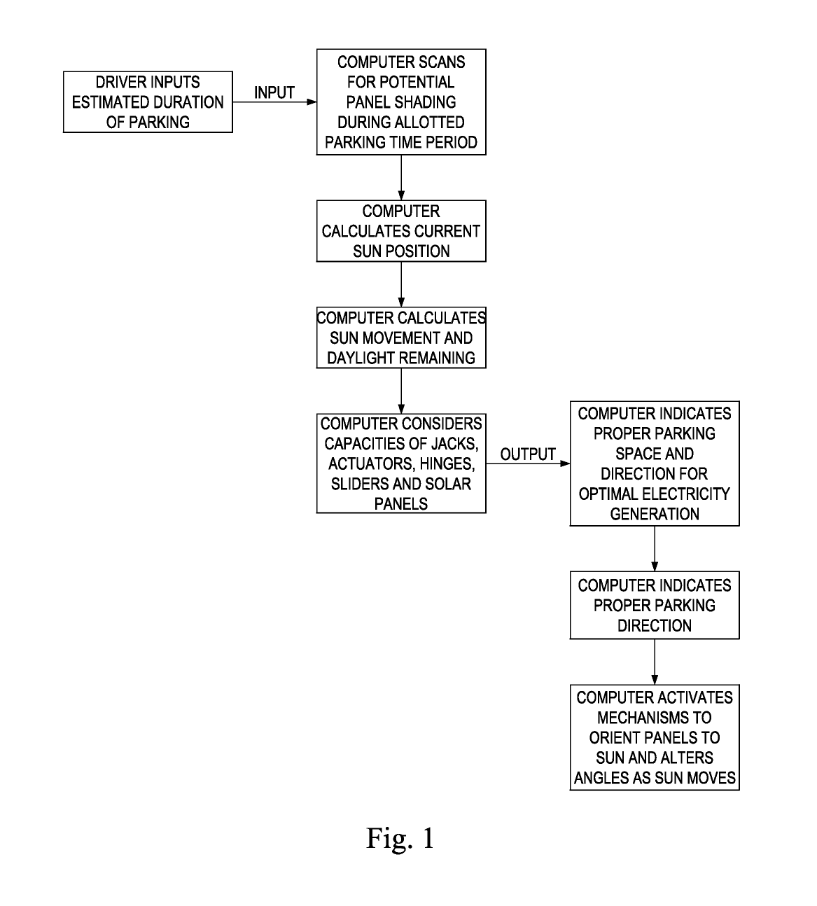

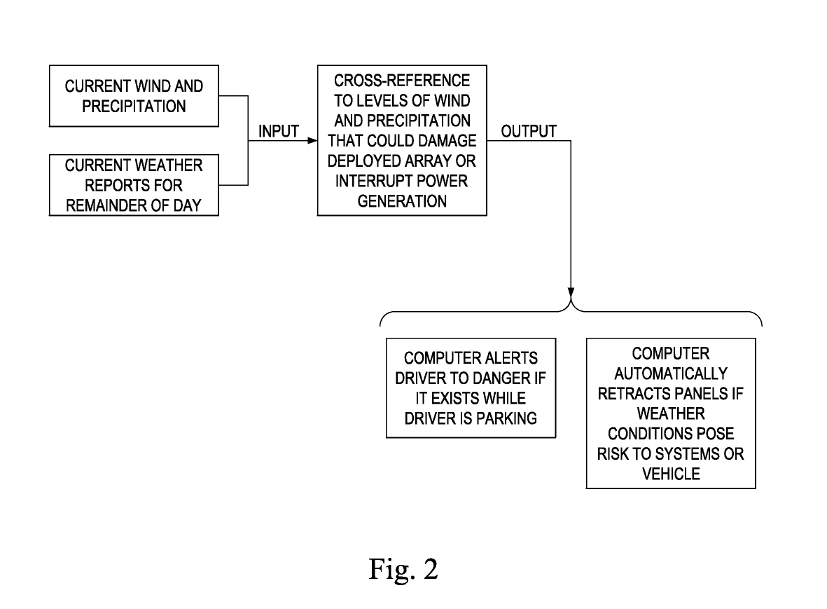

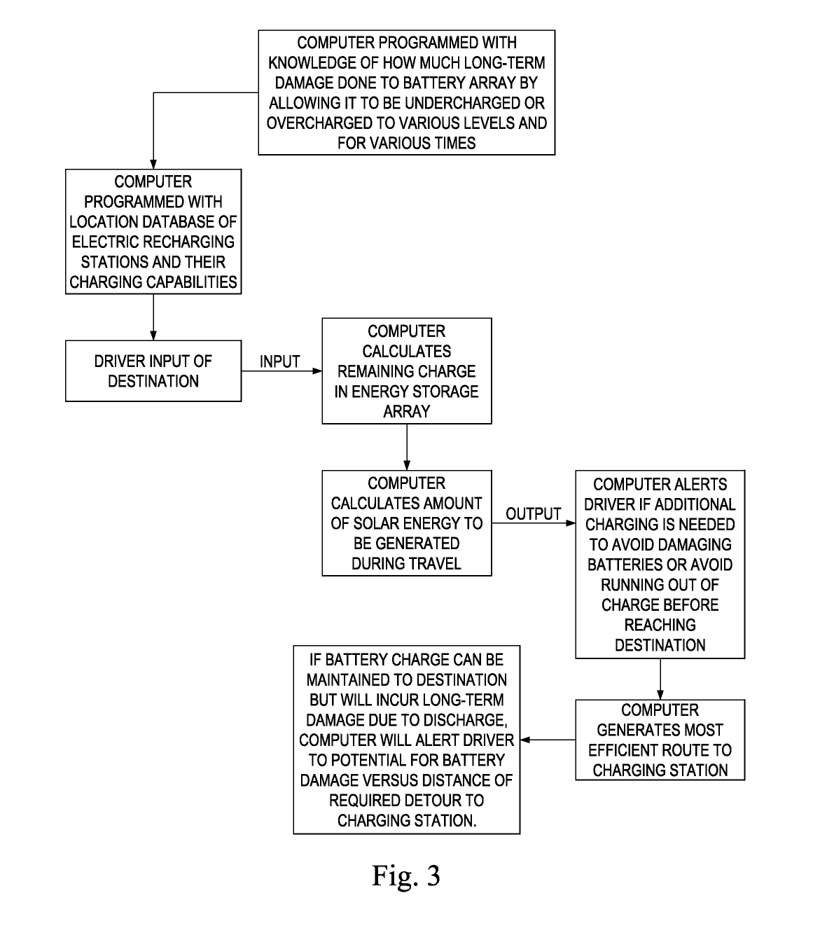

### LIST OF DRAWING REFERENCE NUMBERS

1 solar panel one
2 solar panel two
3 solar panel three
4 actuators to deploy solar array
5 vehicle
6 wheels/tires
7 the sun
8 internal jacks undeployed
9 internal jacks in various stages of deployment
10 outside camera
11 outside sensor
12 Blocks B1 & B2
13 bolts Bt1 & Bt2
14 hinged jack strut
15 Riders R1 & R2
16 Shaft
17 Hinges H1, H3
18 Longer pin of hinge H2
19 Supporting plate

### MORE DETAILED DESCRIPTION OF THE PRESENT INVENTION REFERENCING THE DRAWINGS

The first step in the procedure depicted in figure one is for the driver to input the length of time they plan to remain parked. With that information in mind, the computer will use an outside camera type device to place any nearby objects taller than the lowest deployed solar panel on a form of internal display. Not only will the computer be given preprogrammed knowledge of how the sun is going to move across the sky on any given day, but this will be supplemented by actual observations by a camera type device 10. Related to the above, the computer will also determine how the movement of the sun over this period of time will affect the watts of electricity can be generated by solar panels in various positions. With all this information and considering the mechanisms available to reposition solar panels and raise or lower the vehicle in different ways, the computer will suggest the available parking space which will maximize its ability to generate the most solar electricity possible during the proposed period of time that the vehicle will be parked. It will also suggest the direction of parking within the parking space chosen by the driver which would maximize solar electricity generation over the time when the vehicle is parked. Once the vehicle has been parked, the computer will use the aforementioned information to help it use whatever mechanisms are available to maximize solar electricity generated by orienting the array towards the sun as much as possible.

The first step in the procedure depicted in figure two is for an onboard sensor 11 to detect the current wind level and to detect whether it is raining or snowing and, if so, the level of precipitation. The onboard computer will also monitor at least one weather report through the vehicle radio or another device. With this information in mind, the onboard computer will compare the current and projected level of wind and precipitation to pre-programmed yardsticks which indicate what levels of wind and precipitation might cause damage to an undeployed solar array. If the danger is imminent in accordance with pre-programmed parameters when the driver is parking the vehicle, the computer will alert the driver and suggest that the solar panels not be deployed. If the danger is not imminent when the vehicle is being parked but it becomes imminent during the period of time when the vehicle is parked, the onboard computer will be authorized to retract the solar array to its less vulnerable undeployed position.

There is one important area where the first and second procedures could overlap. As per figures four and five, a vehicle could be made in such a way that its solar array's orientation to the sun was primarily based on a combination of where one parked the vehicle and of how one angled the solar array. One way that the solar array could create this effect would be by using actuators and similar other mechanisms to raise some solar panels (for instance solar panel 1) higher off the roof than other solar panels (for instance solar panel 3). In general, figure four depicts a system where these type of mechanisms 4 were used to put solar panels 1,2 and 3 on different levels with those closest to the south being lower after proper parking. Although there is overlap in what type of actuators 4 and similar mechanisms are used and the final results, figure five can more generally be seen as showing how a coordination of actuators 4 and similar mechanisms would be used to create an overall tilt wherein all the deployed solar panels 1,2 and 3 end up on the same plane. Proper parking would insure that this tilted array would be lower in its southernmost edge and then get higher off the ground as one moves northwards. While this second configuration depicted in figure five would tend to improve the electricity generation ability of the array, the difference is not great enough that the higher cost of creating a perfect tilt with all solar cells on the same plane is always justified. But what is necessary within the terms of the present invention is for the combination of carefully considered parking and the use of mechanisms would create the following effects:

As long as the vehicle is properly parked with the lowest panel oriented towards the sun, no panel can shade another one, the lowest point on the southernmost edge of the deployed solar array is at least as low as any other part of the array, the average height of the deployed array would go up as one moves further north and the highest point on the northernmost edge of the deployed solar array would be at least as far off the ground as any other part of the solar array.

To almost exactly the same extent as placing solar panels on an angled roof of a structure where the southernmost part of the array was the lowest, this would orient the array towards the sun.

But this system of creating one specific positioning of the deployed solar array only succeeds in partly orienting a solar array towards the sun. The fundamental problem is that the sun moves to different positions in the sky depending on the month and the time of day. To understand how the prime embodiment of the present invention is able to fine-tune the array's positioning to track the sun's movements, one should consider figure six.

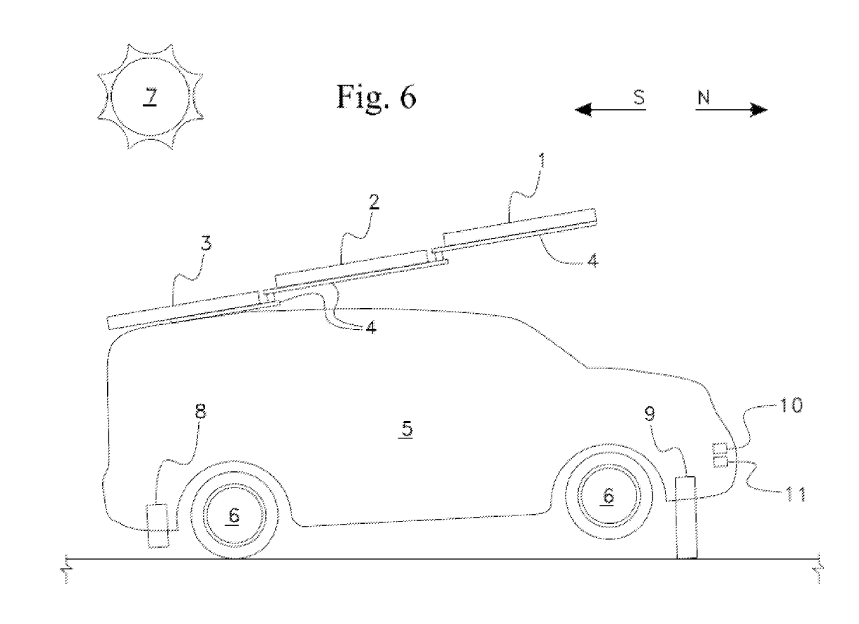

Please compare the undeployed internal jack 8 near the rear of the vehicle to the deployed internal jack 9 near the front of the vehicle. As shown in FIG. 6, the deployed internal jack 9 has the effect of raising one corner of the vehicle to a position where the closest tire 6 is not touching the ground. The undeployed internal jack 8, on the other hand, does not raise the vehicle above the level where the closest tire 6 is touching the ground. One could, for instance, raise one corner a foot, not raise the opposite corner at all and then raise the other two corners just enough that all four corners were supported by either tires or jacks touching the ground. By varying which of the four corners was highest, using proper parking and the solar array deployment system outlined with reference to figures four and five, one could essentially track the sun in a similar way to how a two axis tracker tracks the sun on a stationary solar array. Besides the ability of this system to track the sun, it could often be used to compensate for a drivers inability to find a perfectly positioned parking space in the first place.

If a consumer wanted to save money, they could almost always properly track the sun and compensate for their inability find a perfectly positioned parking space by the use of only two internal jacks. Assuming that the mechanisms used to reposition the individual solar panels in their deployed position was set up to create an angle that is higher in the front of the vehicle, one jack on each front corner of the vehicle would work. (on the other hand, one jack on each corner of the rear of the vehicle would work if the mechanisms used to reposition the individual solar panels in their deployed position was set up to create an angle that is higher in the rear of the vehicle). The only problem with using only two internal jacks 8 and 9 as outlined in the last sentence and the semi-sentence in parenthesis is that it would often result in one of the two tires 6 where there was no nearby internal jack 8 or 9 being slightly above the ground. The effect would be that the vehicle would only be supported on three corners.

Except in extreme weather or if the vehicle is parked on a steep incline, a parked vehicle supported only on three corners would be fine. It is because of the possibility of extreme weather and parking on an incline that there would be another overlap between the computer functions depicted in figures one and two. While the aspect of the computer which dealt with maximizing solar electricity output would often position the parked car in such a way that only three sides were supported, the aspect of the computer which dealt with protecting the solar panels and the vehicle would have the ability to over-rule the solar orientation aspect of the computer. Of course, the vehicle would normally have only one onboard computer and computer “thinking” isn't governed by egocentric desires of one aspect to control or over-rule the other when it is inappropriate to do so. In practice, therefore, the aspect of the computer depicted in figure one and the aspect depicted in figure two would work together to maximize solar energy output as long as doing so didn't put vehicle stability or the solar panels in jeopardy.

The first step of the procedure depicted in figure three is for the driver to input an onboard computer with the destination they intend to drive to. Using a GPS type system, the computer will calculate the mileage to that destination. The computer will then compare the miles to that destination to the charge of the energy storage devices (or battery array) and consider how much lower the charge will become (counting the probable solar energy output during the drive if there is to be any solar energy output during the drive). If the final projected charge level is low enough to cause potential long-term damage to the battery or lower, then the computer will also calculate the detour distance and time required to go to battery recharging stations on the way to recharge the batteries. If the final projected charge level is only slightly above the charge level that could cause long-term damage to the battery array, the computer will ask the driver to tell it about its next proposed drive and consider that information in the context of future weather and sun movement projections. Using all this knowledge, the computer will alert the driver to the pros and cons of stopping at particular battery recharging stations or of trying to make the trip with no stops. These pros and cons will include the likelihood of long-term damage to the battery array, the amount of potential long term damage and the possibility of actually running out of charge and being unable to continue driving the vehicle. Based on this information, the driver will make the ultimate decision about whether and where to stop for recharging.

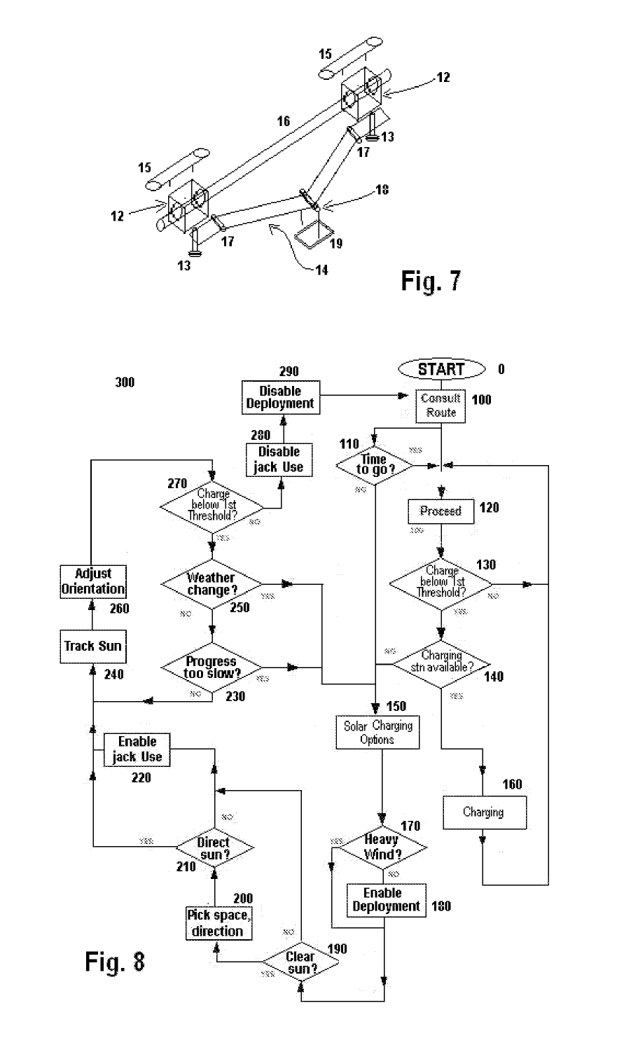

A particular exemplary embodiment of a non-intrusive internal jack to be used with the present invention is illustrated in FIG. 7. The jack is specially adapted for the type of constant adjustment, small excursion, light duty contemplated by the present invention, while retaining much capability of vehicle-maintenance purposes already in use. Blocks B1 & B2 (12) are bolted by Bt1 & Bt2 (13) to the hinged jack strut. (14) Riders R1 & R2 (15) are captively held by longitudinal grooves (not shown) in the bottom of the car, such that they may move parallel to the car length in response to an electric motor connected to the shaft and, in an embodiment, controlled by a computer.

Shaft (16) is turned by a computer-controlled motor to cause controlled, stable flexing of the strut. Blocks 12 and shaft 16 are enabled via threading to displace with respect to each other. It should be noted that, as is generally known in the mechanical arts, one or the other of a shaft and a block may forego threading and yet achieve stable, adjustable displacement as is disclosed in the present invention. One element may simply have Chiralities of threaded members are oppositely selected such that turning causes blocks to either converge or diverge, in a manner known to jack design. A person having skill in the mechanical arts would appreciate that different but similar choices could accomplish this specific aspect. The shaft is articulated at hinges H1 H3 (17) and also at extra long-pin hinge H2 (18) which has its ends fixed to supporting plate, (19) enabling pivoting support, under load, of vehicle. The vehicle has typically up to 4 of these jacks, all though in the case of an extremely heavy vehicle a need might exist for more. In such a case normal solar collection operation would involve coordinating multiple jacks to act together while being adjusted.

Lightweight, out of the way, able to work with the computer, in combination with a block or pile of boards placed by user if necessary, to provide a couple of inches or so of vertical freedom when the vehicle is parked. In the case of the need for maintenance duty such as a wheel change, the effective excursion of the jack may be supplemented by iterative placing of parallel piles of objects next to the jack to temporarily support the vehicle, then contracting and re-extending the jack under the vehicle with a higher supporting boost placed under supporting plate 19. The riders 15 may be allowed removal from the grooves (not shown) for stowing, in a manner known for example to shelf-mount design,

For purposes of Flowchart FIG. 8, ‘true’ and ‘yes’ mean the same, as do ‘false’ and ‘no’. 100 may include consulting weather reports, GPS, locations of charge stations along the way, battery characteristics & state and other factors as described in the spec.

At 110, if the car is parked and it is not yet time to leave, only charging options 150 are available, as opposed to the traveling charge options beginning at 140.

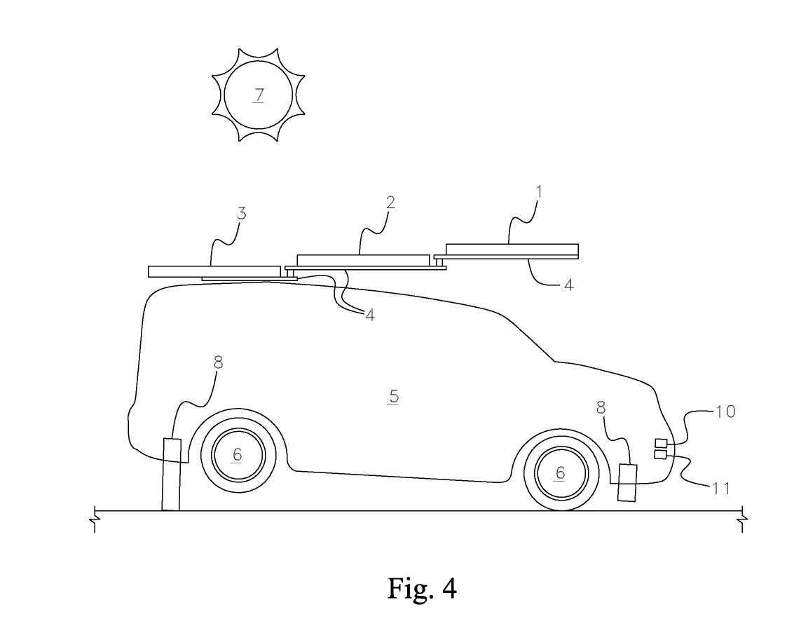

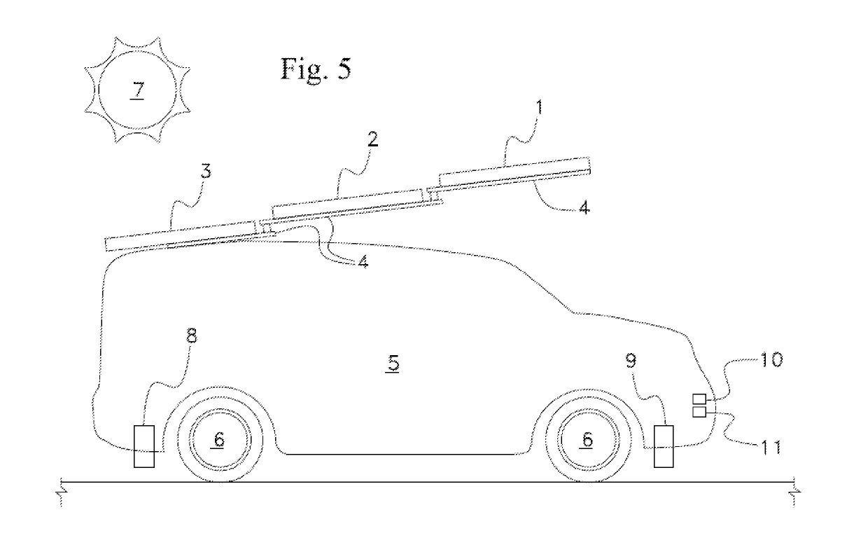

120 indicates normal travel, 160 indicates plug-in charging. Step 180 means to enable unfolding or deployment of the solar panel configuration shown at FIG. 4 1, 2 & 3. It does not necessarily mean that they are immediately extended, but that a flag or environment variable or the like is set in the computer algorithm, signaling that such extension as is indicated by calculations to be beneficial for charging, are permitted to be altered in a real-time way. The meaning of ‘enable’ for the purposes of step 220 is similar. ‘Enabling’, as described elsewhere in this document, may further be accompanied by messages to the user requesting some action to unhook, or make mechanical or electrical connections, or in the case of the jacks to prepare, for optimal excursion capability, for example, by boosting them, or by slightly altering the vehicle or setting a parking brake or bricks behind the wheel to ensure the car will not move while the jacks are moving.

Although not shown, an alternate embodiment which anticipates that the car is likely parked at a place where a charging station is located, would omit step 110 and therefore the question at 140 would include a ‘yes’ without travel. At 150, processing may evaluate many options pertaining to conditions. If test at 170 returns ‘true’, full deployment of the solar panel as described in the spec is dispensed with Step 190 asks whether the sun is likely to be coming from a highly predictable spot. Step 200 may have prior information from 100 concerning solar history for available parking spaces to assist with the decision as to which is likely to be best during the anticipated parking period and is most accessible. In step 210, ‘true’ implies that local object shading and anticipated path of the sun during the charging period will be so clear (already found true at 190) and directly overhead that only such positioning of the panels will be used, and there is no need to enable jack use at 220. Otherwise, step 220 signals to the computer that jacks may be used to change the orientation of the vehicle if helpful for charging, as further described in the spec.

At 240 the camera monitors the sun including shade caused by objects. At 260, whichever adjustment options have been selected according to 150 & 220. These processes are iterated many times, very quickly so as to keep a near real time optimal adjustment. As long as charging progress as indicated in step 230 is satisfactory, the test at 270 gives true and 250 does not indicate that local conditions have changed to warrant changing the options starting at 150, the 240/260 cycle continues.

Step 250 quickly sends processing back to step 150 in the event of sudden changes in weather such as high winds, that might warrant folding the solar panels back into a safer configuration. If so, charging continues as such.

At steps 280 & 290, jacks and panels are returned to their traveling positions. It is possible, in an alternate embodiment, that the two threshold levels indicated at 130 & 270 might not be the same, such as in the case where the computer determines that only a little bit of solar charging is necessary, for example when data indicates that, with a short-term charge, the vehicle may be expected to enter a region of travel where many charging stations will exist even though none are currently available. In such a case there is no point in squeezing extra energy out of the solar charging procedure immediately.

Although the terms and definitions used in the specification are intended to be read into the claims they are hot intended to limit the meets and bounds of the claims presented here below in any manner whatsoever.

I claim:

1. A vehicle which uses electric power for at least a portion of its propulsion;
a) a solar array which covers a smaller footprint in the undeployed configuration and a larger footprint in the expanded or deployed configuration
b) tilting means connected to the solar array and wherein said tilting means is adapted to at least impart to said array, when in the deployed configuration, a restorable tilt
c) wherein the portion of the array located near either the front perimeter or the back perimeter of the vehicle will be closer to the ground than the average height of all the solar cells in the vehicle solar array
d) wherein said solar panel array is firmly affixed sufficiently in the retracted and undeployed state to permit highway travel and so as to withstand wind.

2. The vehicle of claim 1 wherein
When the vehicle is parked with the lowest panel oriented towards the sun, in its deployed state, no panel of the array is disposed so as to substantially shade another one.

3. The vehicle of claim 2 wherein said tilting-means comprises
a) at least one internally-mounted jack.

4. The vehicle of claim 3 wherein said tilting-means comprises
a) at least two internally-mounted jacks
b) wherein at least two of said jacks are positioned with respect to a cartesian axis of the car chassis
c) at least one 12-volt or other electric supply for at least one of said jacks.
d) wherein said jacks are capable of effecting a vertical adjustment in a substantially real-time manner and;
e) wherein further said jacks are constructed of parts sufficiently convenient to be installed on the vehicle by a consumer

5. A method of parking a vehicle having a rooftop solar collector array further comprising the steps of
a) elevating the front or the rear of the array;
b) selecting a parking location so as to maximize solar collection;
c) periodically adjusting the lateral tilt of the array as appropriate to maximize solar collection
d) selecting a parking direction for the vehicle such that the solar panels which are lower are south of the solar panels that are higher off the ground;

6. The method of claim 5 wherein said selecting a parking location or direction further comprises
excepting cases consisting of locations which would cause parts or all of the solar array to be shaded during part or all of the particular period of time when the vehicle is parked.

7. The method of claim 6 further comprising, in said excepted cases, determining where and in which direction to park the vehicle so as to avoid shading that would reduce the total solar generated electricity produced to a level lower than it would be in any other parking space and parking direction acceptable to the driver.

8. A non-transitory computer-readable storage medium that stores a program for causing a computer to execute a control method for an electric vehicle solar array recharging apparatus comprising;
a) a solar panel position calculating unit,
b) a light sensor providing information to the processor
c) a solar power temporal prediction unit
d) a vehicle operation modification evaluation unit and
e) wherein said information is based on an evaluation of those costs and benefits of vehicle operation which impact effectiveness of different available solar charging options and
f) is directed to said processor to calculate ideal orientation of the solar cells.
g) a solar panel repositioning unit which generates signals based on calculations produced by said solar panel position calculating unit,
h) wherein said operation modification unit provides information affecting gross behavior of the vehicle
i) wherein said processor further monitors environmental safety conditions provided at least in part by said light sensor to determine whether to retract the solar array to the safer undeployed and unexpanded position

9. The non-transitory computer-readable storage medium of claim 8 further comprising a GPS system.

10. The non-transitory computer-readable storage medium of claim 8 wherein
a) said operation modification unit further comprises a parking location evaluation unit.
b) said environmental safety conditions comprise nearby objects which might cause damage while deploying the array.

11. The non-transitory computer-readable storage medium of claim 10 further comprising a GPS system.

12. The non-transitory computer-readable storage medium of claim 9 wherein
a) said light sensor is an image sensor
b) and a charging station/trip calculator tradeoff evaluation unit
c) a charging system safety/effectiveness tradeoff evaluation unit
d) wherein said safety conditions comprise presence of passing vehicular traffic which might present a complication in driving with a partially or fully-deployed array.
e) a. weather evaluation unit to determine, on the basis of monitored weather information, whether to retract the solar array to a safer undeployed and unexpanded position in the event of wind or extreme precipitation.

13. The non-transitory computer-readable storage medium storing a program of claim 8 wherein at least one of said charging options represents a parking space where a solar panel may be deployed and a direction of parking in that parking space and;
wherein said processor further has access to an image sensing array which is adapted to process information to monitor solar availability as affected by characteristics of said parking space and surrounding area which could not have been anticipated by a GPS system.

14. The non-transitory computer-readable storage medium storing a program of claim 12 wherein said program further comprises
a) an axial positioning unit connected to tilting means for controlling a tilt of said array and;
b) a calibration routine unit for maximizing effectiveness of said axial positioning unit in collecting solar energy by varying said tilt.

15. The non-transitory computer-readable storage medium storing a program of claim 14 wherein
a) said tilting means comprise vehicle-mounted jacks
b) A communication unit that
passes information from the driver to said processor regarding the length of stay in a particular area and
passes information from said processor to the driver to help determine which open parking spaces are close enough to the destination to be acceptable, given those choices of potential parking spaces and which parking space will produce the most electricity and suggests to the driver in which direction to park the vehicle.
c) wherein said solar power temporal prediction unit determines for each potential parking space how the sun will move across the sky during the length of time when the vehicle will be parked and anticipates shading and sun position during the charging period in the parking space,
d) an evaluation unit that evaluates alternative potential parking spaces based on the total amount of solar energy that could probably be produced

16. The non-transitory computer-readable storage medium storing a program of claim 15 further comprising a safe deployment unit connected to said camera which will direct, when the vehicle is parked, said axial positioning unit to reposition the solar panels in a way which maximizes solar electricity generation as much as possible while avoiding moving solar panels into positions which would hit nearby people or vehicles or go into an area that is not within the parking space assigned to the vehicle.

17 The non-transitory computer-readable storage medium storing a program of claim 12 further comprising a safe maximal excursion unit monitoring safe maximal excursion of suspension play including vehicle loading and terrain slope.
